(19) United States
(12) Patent Application Publication
(10) Pub. No.: US 2008/0253888 A1
(43) Pub. Date: Oct. 16, 2008

(54) COOLING FAN

(75) Inventors: CHENG-FANG HSIAO, Tu-Cheng (TW); I-SUNG TSAI, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Tu-Cheng (TW)

(21) Appl. No.: 11/831,917

(22) Filed: Jul. 31, 2007

(30) Foreign Application Priority Data
Apr. 13, 2007 (CN) 200710074017.1

(51) Int. Cl. F01D 25/16; H05K 7/20

(52) U.S. Cl. 415/229; 361/695

(57) ABSTRACT

A cooling fan includes a base (31), an impeller (33), a magnetic ring (38) and a stator (30). The base has a central tube (311) extending upwardly therefrom. An annular protrusion (313) is formed around the tube near a bottom end thereof. The protrusion is homocentric with the tube. The impeller includes a hub (332) and a shaft (333) extending downwardly from a central portion of the hub. The stator is mounted around the protrusion. An annular space (320) is defined between the stator and the tube. The magnetic ring is received in the annular space, and is fixedly mounted around the shaft to rotate with the shaft during operation of the cooling fan.

### BACKGROUND OF THE INVENTION

1. Field of the Invention

The present invention relates to a cooling fan, and more particularly relates to a cooling fan which is simple in construction, and has high drive torque efficiency.

2. Description of Related Art

With the continuing development of the electronic technology, electronic packages such as CPUs (central processing units) are generating more and more heat that requires immediate dissipation. Cooling fans are commonly used in combination with heat sinks for cooling CPUs.

A conventional cooling fan includes a stator, a rotor rotatable with respect to the stator, and a fan housing receiving the rotor and the stator therein. The stator typically includes a stator core and stator coils wound around the stator core. The stator core consists of layered yokes. Each yoke includes a ring shaped central portion and a plurality of pole members extending radially and outwardly from the central portion for winding the coils thereon. The rotor includes a hub with a cylinder-shaped permanent magnet adhered to an inner surface thereof surrounding the stator. During operation of the fan, an alternating magnetic field emitted by the stator interacts with a magnetic field of the permanent magnet to drive the rotor to rotate, thereby generating an airflow. However, the yokes of the stator core are formed by stamping silicon-steel sheets, each of which has a flat configuration and a predetermined diameter; thus, the size and the shape of the stator core are essentially fixed and difficult to be altered. Due to the essentially fixed size and shape of the stator, winding of the coils is difficult and time-consuming, thereby resulting in high rejection rate of the product. Furthermore, the pole number and the phase number of the stator cannot be easily increased and thus results in a dead point problem, which prevents operational stability of the fan from being effectively enhanced.

For the foregoing reasons, therefore, there is a need in the art for a cooling fan which overcomes the above-mentioned problems.

### SUMMARY OF THE INVENTION

According to a preferred embodiment of the present invention, a cooling fan includes a base, an impeller, a magnetic ring and a stator. The base has a tube extending upwardly therefrom. An annular protrusion is formed around the tube near a bottom end thereof. The protrusion is homocentric with the tube. The impeller includes a hub and a shaft extending downwardly from a central portion of the hub. The stator is mounted around the protrusion, and includes a stator core having a plurality of teeth being alternately arranged along a circumferential direction thereof and an axial coil winding around the teeth. An annular space is defined between the stator and the tube. The magnetic ring is received in the annular space, and is fixedly mounted around the shaft so as to rotate with the shaft during operation of the cooling fan.

Other advantages and novel features of the present invention will be drawn from the following detailed description of a preferred embodiment of the present invention with attached drawings, in which:

### BRIEF DESCRIPTION OF THE DRAWINGS

Many aspects of the present cooling fan can be better understood with reference to the following drawings. The components in the drawings are not necessarily drawn to scale, the emphasis instead being placed upon clearly illustrating the principles of the present cooling fan. Moreover, in the drawings, like reference numerals designate corresponding parts throughout the several views:

FIG. 1 is an assembled, cross-sectional view of a cooling fan in accordance with a preferred embodiment of the present invention;

FIG. 2 is an exploded view of FIG. 1;

FIG. 3 shows an assembled, cross-sectional view of the cooling fan in accordance with a second embodiment of the present invention;

FIG. 4 is an exploded view of FIG. 3;

FIG. 5 is an isometric, assembled view of the cooling fan of FIG. 3; and

FIG. 6 shows an assembled, cross-sectional view of the cooling fan in accordance with a third embodiment of the present invention.

### DETAILED DESCRIPTION OF THE INVENTION

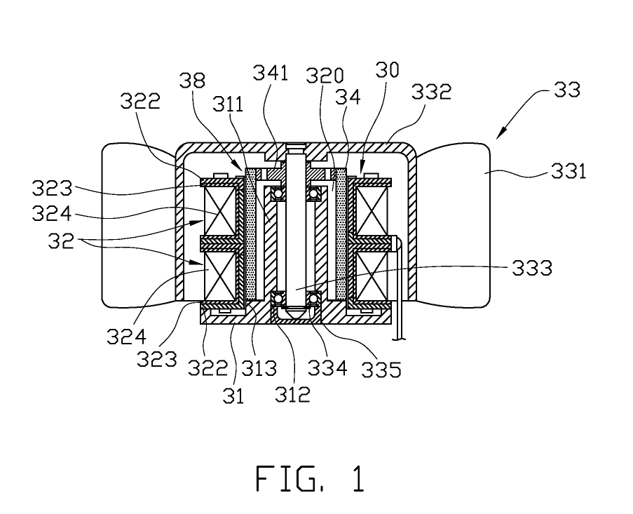

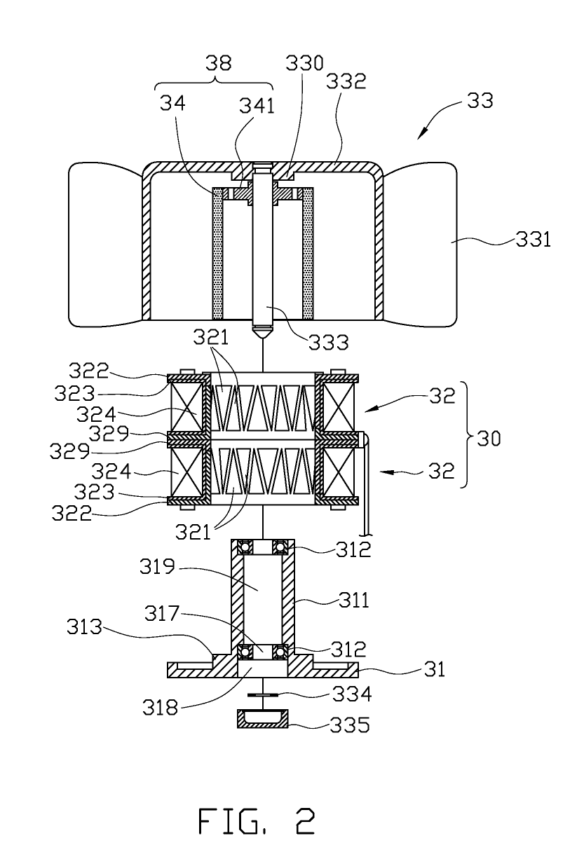

As shown in FIGS. 1-2, a cooling fan according to a preferred embodiment of the present invention includes a base 31, a stator 30, an impeller 33, and a magnetic ring 38.

The impeller 33 includes a hub 332 forming a shaft seat 330 at a central portion thereof and a shaft 333 extending downwardly from the shaft seat 330. A plurality of blades 331 extends radially and outwardly from an outer periphery of the hub 332. The shaft 333 has a top end connecting to the hub 332, and a free bottom end opposite the top end. An annular slot (not labeled) is defined in an outer surface of the shaft 333 near the free bottom end of the shaft 333. The magnetic ring 38 is mounted around the shaft 333 near the top end thereof. The magnetic ring 38 includes an annular shaped holder 341 and a cylindrical permanent magnet 34 extending downwardly from an outer periphery of the holder 341. The holder 341 is fixedly mounted around the shaft 333 and rotates with the shaft 333 when the impeller 33 rotates during operation of the cooling fan. The magnet 34 has a top end being fixedly connected to the outer periphery of the holder 341, and thus the magnet 34 can rotate with the holder 341 and the impeller 33. The magnet 34 is magnetized in segments along its circumference. Each segment is radially magnetized in an opposite direction to its adjacent segments. In other words, the magnet 34 is multipole, in which north poles and south poles are alternate along a circumferential direction of the magnet 34.

The base 31 is circular shaped. A central tube 311 extends upwardly from a center of the base 31. The tube 311 has an outer diameter smaller than an inner diameter of the magnet 34. A through hole 319 is defined in the tube 311. A pair of end openings 318 are defined in top and bottom ends of the tube 311, respectively. Each end opening 318 is larger than the through hole 319 of the tube 311 in diameter. A pair of ball bearings 312 are received in the end openings 318, respectively. It is to be understood that the bearings of the cooling fan is not limited to ball bearing; the bearings can be other types, such as sleeve bearings or fluid dynamic bearings. Each bearing 312 defines a bearing hole 317 therein. The bearing hole 317 has a diameter approximately the same as that of the shaft 333, whilst smaller than that of the through hole 319 of the tube 311. When assembled, the free bottom end of the shaft 333 extends through the bearing hole 317 of the top bearing 312 and then the through hole 319 of the tube 311, and finally through the bearing hole 317 of the bottom bearing 312. A cover 335 couples to a bottom of the bottom end opening 318 and thus seals the bottom end of the tube 311. The cover 335 has a U-shaped cross section, including a circular shaped bottom wall (not labeled) and an annular sidewall (not labeled) extending upwardly from an outer periphery of the bottom wall. The cover 335 is made of high abrasion resistant material. A top of the sidewall of the cover 335 abuts against the bottom bearing 312, and an upper surface of the bottom wall of the cover 335 abuts the free bottom end of the shaft 333. An annular protrusion 313 is formed around the tube 311 near the bottom end thereof. The protrusion 313 is homocentric with the tube 311. An outer diameter of the protrusion 313 is approximately the same as an outer diameter of the magnet 34.

The stator 30 is ring shaped with an inner diameter substantially the same as an outer diameter of the protrusion 313 of the base 31. The stator 30 is mounted around the tube 311 with a bottom end thereof surrounding the protrusion 313. Thus an annular space 320 for receiving the magnet 34 is defined between an outer surface of the tube 311 and an inner circumference of the stator 30 above the protrusion 313. The stator 30 includes a stator core (not labeled) having two claw-pole assemblies 32 (i.e., an upper claw-pole assembly 32 and a lower claw-pole assembly 32) arranged back-to-back and are misaligned from each other by an electrical angle of 90°. Each claw-pole assembly 32 includes an outer yoke 322 and an inner yoke 329 facing towards each other. Each yoke 322, 329 is ring-shaped. A plurality of pole teeth 321 extend perpendicularly from an inner circumference of each yoke 322, 329 and are evenly spaced from each other along a circumferential direction of the yoke 322, 329. The pole teeth 321 of the inner and outer yokes 329, 322 of each claw-pole assembly 32 are intermeshed with each other and thus cooperatively form a cylinder-shaped mounting wall. Along a circumferential direction of the mounting wall, the teeth 321 of the outer and inner yokes 322, 329 of each claw-pole assembly 32 are arranged in alternating fashion, and are misaligned from each other by an electrical angle of 180°. An axial coil 324 winding around a bobbin 323 is disposed between the inner and outer yokes 329, 322 and mounted around the mounting wall of each claw-pole assembly 32.

When the cooling fan assembled together, the shaft 333 extends through the bearing holes 31 7 of the two bearings 31 2 and the through hole 31 9 of the tube 311. The free bottom end of the shaft 333 abuts against the bottom wall of the cover 335. The slot (not labeled) of the shaft 333 adjacent to the free bottom end thereof is located under the bottom bearing 312. A locking ring 334 is mounted around the shaft 333 and is received in the slot of the shaft 333. The locking ring 334 has an inner diameter larger than the diameter of the shaft 333 at the slot, whilst smaller than other portion of the shaft 333. An outer diameter of the locking ring 334 is larger than the diameter of the bearing hole 317; thus, atop side of the locking ring 334 abuts the bottom bearing 312 for limiting movement of the impeller 33 along an axial direction of the shaft 333. The holder 341 of the magnetic ring 38 is located on the top bearing 312. The magnet 34 is received in the space 320 between the stator 30 and the tube 311. During operation, the axial coils 324 wound around the yokes 322, 329 establish an alternating magnetic field which interacts with the magnetic field of the magnet 34 of the magnetic ring 38 thus driving the impeller 33 to rotate. As the stator core has a plurality of pole teeth 321, the pole number and the phase number of the stator 30 are much increased. As a result, the operational stability of the cooling fan of the present invention is enhanced. In an alternate layout of the phase number, the operational dead point of the present invention is eliminated and thus the operational stability of the present cooling fan is enhanced. Furthermore, the pole teeth 321 are disposed in the inner side of the stator 30, while the coils 324 are wound on the outer side of the stator 30. Winding coils for the present cooling fan is thus simplified, thereby resulting in both easy and convenient production and assembly of the cooling fan.

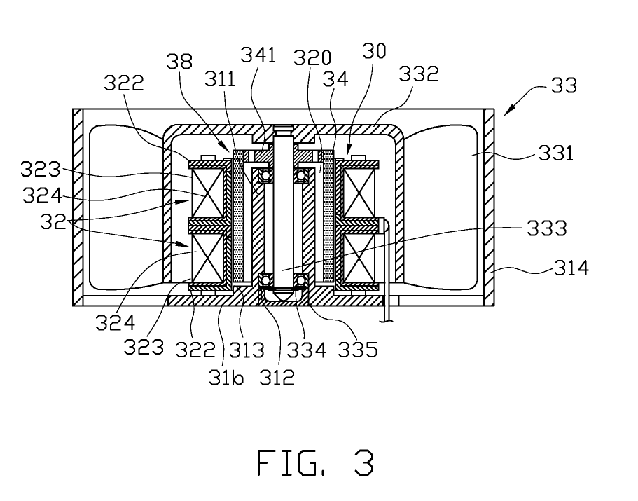

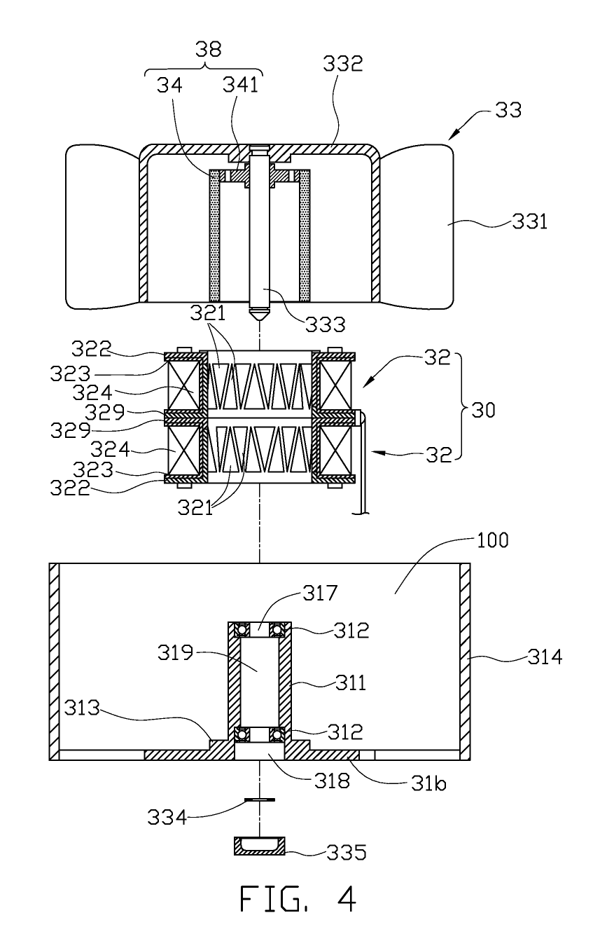

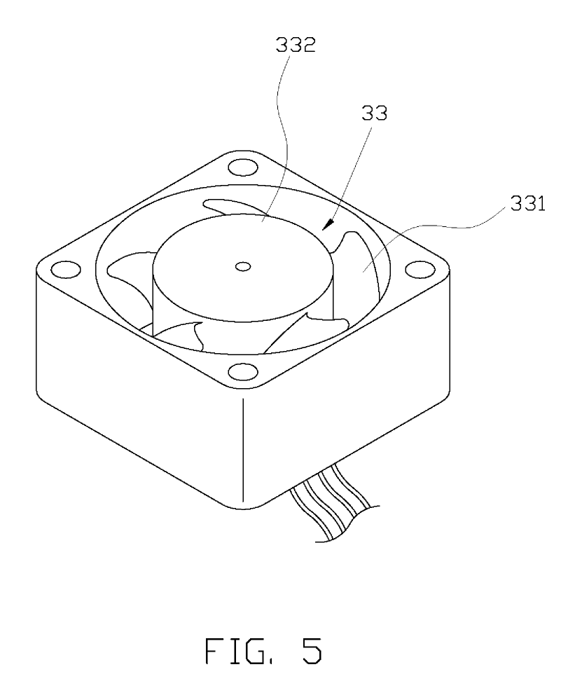

FIGS. 3-5 illustrate the cooling fan in accordance with a second embodiment of the present invention. The difference between the second embodiment and the first embodiment is that the cooling fan according to the second embodiment further includes a fan housing 314. As other parts of the cooling fan according to the second embodiment are substantially the same as the cooling fan of the previous embodiment, except for the fan housing 314, other parts already described are not described. The fan housing 314 has a profile generally being cuboid. A column shaped chamber 100 is defined in a central portion of the fan housing 314 receiving the base 31b, the stator 30, the impeller 33 and the magnetic ring 38 therein. A bottom end of the fan housing 314 connects to an outer periphery of the base 31b.

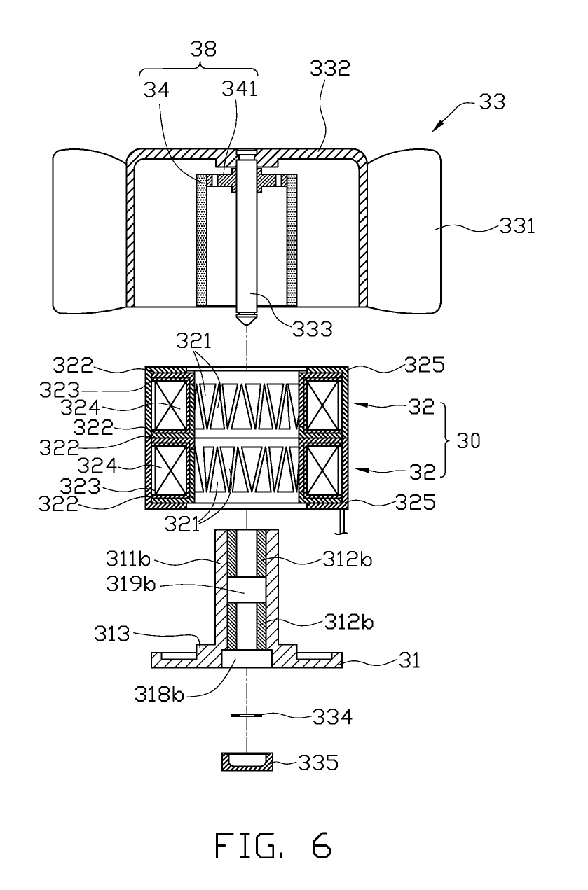

FIG. 6 shows a third embodiment of the cooling fan. Similar to the first embodiment, the cooling fan includes the base 31 forming the central tube 311b, the stator 30, the impeller 33 and the magnetic ring 38. Also the protrusion 313 is formed around the bottom end of the tube 311b, the stator 30 is mounted around the protrusion 313, and the magnet 34 is received in the space 320 defined between the tube 311 and the stator 30. The difference between the third embodiment and the first embodiment is that two sleeve bearings 312b are included in the third embodiment to replace the ball bearings 312 of the first embodiment. The two bearings 312b are received in the through hole 319b of the tube 311b by press fitting. The two bearings 312b are respectively arranged at two opposite sides of the tube 311b, and are spaced from each other. Also the tube 311b defines an end opening 318b in a bottom end thereof receiving the cover 335 therein to seal the bottom end of the tube 311b. In addition, the cooling fan of the third embodiment further comprises a pair of shells 325 made of electrically conductive material mounted around the stator 30 and receiving the stator 30 therein to enhance the magnetic field established by the stator 30. The two shells 325 face towards each other. Each shell 325 includes an annular shaped base portion and a cylindrical-shaped side portion extending perpendicularly from an outer periphery of the base portion. Cooperatively the two side portions forms a sidewall around the stator 30. The two base portions are arranged at top and bottom sides of the stator 30, respectively.

It is understood that the invention may be embodied in other forms without departing from the spirit thereof. Thus, the present example and embodiment is to be considered in all respects as illustrative and not restrictive, and the invention is not to be limited to the details given herein.

What is claimed is:

1. A cooling fan comprising:
a base having a tube extending upwardly therefrom, an annular protrusion being formed around the tube near a bottom end thereof and being homocentric with the tube;
a stator being mounted around the protrusion and cooperatively defining an annular space between the stator and the tube, the stator comprising a stator core having a plurality of pole teeth being arranged in an alternating fashion along a circumferential direction thereof, and an axial coil winding around the teeth;
an impeller comprising a hub and a shaft extending downwardly from a central portion of the hub; and
a permanent magnet being received in the space, and being fixedly mounted around the shaft to rotate with the shaft during operation of the cooling fan.

2. The cooling fan of claim 1, further comprising a holder being fixedly mounted around the shaft, the magnet being fixedly mounted around the holder.

3. The cooling fan of claim 2, wherein the holder is located above the tube and is disposed near a top end of the shaft.

4. The cooling fan of claim 1, wherein the tube defines a through hole receiving a pair of bearings at two opposite ends thereof for extension of the shaft therethrough to support rotation of the impeller.

5. The cooling fan of claim 4, wherein the tube defines two end openings larger than the through hole in diameter at two opposite ends thereof, each opening receiving one of the two bearings therein.

6. The cooling fan of claim 4, wherein the bearings are selected from at least one of the following types: sleeve bearing, ball bearing and fluid dynamic bearing.

7. The cooling fan of claim 4, further comprising a cover coupling to the bottom end of the tube and thus sealing the bottom end of the tube.

8. The cooling fan of claim 1, wherein the stator core comprises a plurality of stacked claw-pole assemblies, each claw-pole assembly comprising two yokes each forming teeth intermeshed with teeth of the other yoke.

9. The cooling fan of claim 1, further comprising a shell made of electrically conductive material mounted around the stator and receiving the stator therein.

10. A cooling fan comprising:
a base having a central tube extending upwardly therefrom;
an annular protrusion being formed around the tube near a bottom end thereof and being homocentric with the tube;
a stator being mounted around the protrusion, an annular space being defined between the tube and the stator above the protrusion;
an impeller having a shaft extending into the tube; and
a permanent magnet being fixedly mounted around the shaft and being received in the annular space.

11. The cooling fan of claim 10, further comprising a holder located above the tube and fixedly mounted around the shaft near a top end thereof, the magnet being fixedly mounted around the holder.

12. The cooling fan of claim 10, wherein the tube defines a through hole receiving a pair of bearings at two opposite ends thereof for extension of the shaft therethrough to support rotation of the impeller, the bearings being selected from at least one of the following types: sleeve bearing, ball bearing and fluid dynamic bearing.

13. The cooling fan of claim 12, wherein the tube defines two end openings larger than the through hole in diameter in two opposite ends thereof, each opening receiving one of the two bearings therein.

14. The cooling fan of claim 10, wherein the stator comprises a plurality of stacked claw-pole assemblies, each claw-pole assembly comprising two yokes each forming a plurality of teeth intermeshed with those of the other yoke.

15. The cooling fan of claim 10, further comprising a shell made of electrically conductive material mounted around the stator and receiving the stator therein.

16. The cooling fan of claim 10, further comprising a fan housing receiving the base, the impeller, the stator and the magnet therein, the housing connecting to an outer periphery of the base.

17. A cooling fan comprising:
a base having a tube extending upwardly therefrom;
a stator mounted to the base, surrounding the tube, and defining a space between the stator and the tube, the stator having a ring-like configuration and formed with a plurality of pole teeth disposed in an inner side of the stator and a coil winding around an outer side of the stator; and
a rotor rotatably mounted on the stator, having a shaft extending downwardly through the tube, a magnetic ring fixed to the shaft and having a magnet extending downwardly into the space between the stator and the tube, and a plurality of blades for generating an airflow when the rotors rotates relative to the stator.

18. The cooling fan of claim 17, wherein the tube has at least a bearing received therein, and the shaft is fitted in the at least a bearing.
